(19) United States
(12) Patent Application Publication
(10) Pub. No.: US 2007/0275312 A1
(43) Pub. Date: Nov. 29, 2007

(54) Semiconductor device

(75) Inventor: Noriaki Suzuki, Kurokawa-gun (JP)

Correspondence Address: BIRCH STEWART KOLASCH & BIRCH, PO BOX 747, FALLS CHURCH, VA, 22040-0747, US

(73) Assignee: FUJIFILM CORPORATION

(21) Appl. No.: 11/802,181

(22) Filed: May 21, 2007

(30) Foreign Application Priority Data
May 23, 2006 (JP) P.2006-143177

(51) Int. Cl. G03F 1/00

(52) U.S. Cl. 430/5

(57) ABSTRACT

A semiconductor device including a test element for a dielectric breakdown test on conductive patterns formed on a semiconductor substrate, wherein the test element includes: a step pattern which is associated with a step portion formed in an underlying layer which is formed on the semiconductor substrate; a conductive pattern adjacent to the step pattern, the conductive pattern being formed by forming a conductive layer on the step pattern and removing at least part of the formed conductive layer selectively by patterning; a pad which is electrically connected to the conductive pattern; and a substrate contact which is electrically connected to the semiconductor substrate.

### FIELD OF THE INVENTION

The present invention relates to a semiconductor device having a test element for a dielectric breakdown test on capacitors which are formed by conductive patterns on a semiconductor substrate. In particular, the invention relates to a technique which enables electrical evaluation of residues that may occur at the time of formation of patterns.

### BACKGROUND OF THE INVENTION

In devices having circuit patterns such as solid-state imaging devices, the chip size and the intervals between conductive patterns are decreasing as the integration density increases. In such a situation, the electrode gaps in patterning of charge transfer electrodes are also decreasing. To cope with this tendency, for example, a method is employed widely that a first-layer conductive film is formed and patterned into first-layer electrodes, then interelectrode insulating films are formed around the first-layer electrodes, and finally a second-layer conductive film is laid so as to cover the interelectrode insulating films and then patterned.

In conventional solid-state imaging devices, photodiode regions and charge transfer regions that are charge transfer elements (CCDs) are formed in a surface p-type impurity layer of a semiconductor substrate. Charges generated in the photodiode regions are guided to transfer channels that are n-type impurity regions and read out sequentially by applying voltages to charge transfer electrodes of the charge transfer regions. That is, in each charge transfer region, charges generated in the photodiode regions are guided to the transfer channel and then transferred sequentially by applying voltages to gate electrodes (charge transfer electrodes) as charge transfer electrodes/read electrodes which are formed over the transfer channel via a three-layer gate insulating film consisting of a silicon oxide film (SiO), a silicon nitride film (SiN) and a silicon oxide film.

When light shines on the photodiode regions, it is converted photoelectrically into signal charges by the n-type impurity regions. The generated signal charges are moved to the transfer channels when read pulses are applied to the gate electrodes which are the charge transfer electrodes/read electrodes. The signal charges are read out by electric fields that are produced by the read pulses.

As described above, in conventional solid-state imaging devices, the gate insulating film which is formed under the charge transfer electrodes has what is called the ONO structure in which the silicon nitride film as a high-breakdown-voltage film is sandwiched between the oxide films. In recent highly miniaturized solid-state imaging devices, the employment of a gate insulating film (ONO film) having the ONO structure is indispensable for reduction of the thickness of the gate insulating film.

In conventional solid-state imaging devices, the gate insulating film is formed on the substrate surface and the charge transfer electrodes consisting of the first-layer electrodes and the second-layer electrodes are formed on the gate insulating film. A second-layer electrode film is formed after formation of the first-layer electrodes. When the second-layer electrode film is removed selectively by dry etching by using a resist mask, non-dry-etched residues (stringers) may remain behind first-layer electrodes. This raises a problem that a second-layer electrode is connected to the second-layer electrode of an adjacent cell via stringers, in which case DC short-circuiting likely occurs.

In developing such semiconductor devices having small chip sizes, short-circuiting between conductive patterns is a serious problem because it may cause a device failure and hence should be detected early in a test stage. One countermeasure is to form a TEG (test element group) which makes it possible to detect a process variation by electrically evaluating the conductive patterns by detecting short-circuiting between conductive patterns.

The TEG is a parametric-test-dedicated device group formed on a wafer that is separate from products-producing wafers or on a products-producing wafer to judge whether wafers are defective or not. When semiconductor integrated circuits or the like are formed on wafers, test transistors, resistors, diodes, capacitors, etc. are formed on a products-producing wafer at arbitrary positions. A TEG is formed in every chip on a wafer or a predetermined, small number of chips on a wafer or on scribe lines between chips. In still another example, a TEG is formed on a wafer dedicated to a test. The same patterns as in products are provided with terminals to enable input/output of electric signals. A test as to whether conductive patterns are short-circuited or not is conducted on the basis of electric signals thus obtained. A test on such a TEG makes it possible to judge whether the wafer itself is defective.

As a background art, JP-A-2002-164517 (corresponding to US 2002/0063272 A1) is known.

### SUMMARY OF THE INVENTION

As the degree of miniaturization of semiconductor devices increases, the thickness of the gate insulating film is being decreased and the electric fields applied to the oxide film are rapidly becoming stronger. It is known that dielectric breakdown occurs in an oxide film when a strong electric field (10 MV/cm or more) is applied to it. However, dielectric breakdown may also occur in CCDs, for example, when a relatively weak electric field (e.g., 3 MV/cm) continues to be applied to an oxide film. This phenomenon is called TDDB (time-dependent dielectric breakdown) of an oxide film (insulating film) and is a major failure mechanism that lowers the reliability of devices.

However, the conventional TEG is provided for single conductors (e.g., electrodes) and does not have a function of checking mutually related functions of plural conductors (e.g., plural proximity-arranged electrodes such as transfer electrodes). Conventionally, in general, a short-circuiting check is performed in search of residues (stringers) that may occur at the time of formation of wiring patterns. However, in CCDs and DRAMs, the above-mentioned TDDB is considered problematic in which an electric field is concentrated around a residue that remains in filament form and a very low degree of leakage occurs via an the insulating film even if it does not result in short-circuiting. That is, the short-circuiting check is not complete: formation of stringers does not always result in short-circuiting. When stringers exist, in an ordinary energization state, the phenomenon actually occurred that an electric field is concentrated around the stringers to cause leakage via the insulating film in spite of the presence of the insulating film. Such stringers are formed in a structure having a step portion that is formed when conductor films are laminated. Stringers may be formed in a process including a step of forming a metal layer on a step portion which is made of an arbitrary material. If there exists an underlying electrode layer, the probability of short-circuiting is higher. For the above reasons, there is demand for electrical evaluation of stringers.

The present invention has been made in the above circumstances, and an object of the invention is to provide a semiconductor device which enables electrical evaluation of residues (stringers) of conductive patterns including ones that do not result in short-circuiting and to thereby enable detection of a process variation.

The above object of the invention is attained by the following configurations.

(1) A semiconductor device having a test element for a dielectric breakdown test on conductive patterns formed on a semiconductor substrate, wherein the test element comprises:

a step pattern which is associated with a step portion formed in an underlying layer which is formed on the semiconductor substrate;

a conductive pattern adjacent to the step pattern, the conductive pattern being formed by forming a conductive layer on the step pattern and then removing at least part of the conductive layer selectively by patterning;

a pad which is electrically connected to the conductive pattern; and

a substrate contact which is electrically connected to the semiconductor substrate.

In this semiconductor device, with attention paid to the fact that residues (stringers) occur particularly in step portions, not only the pad for connection to the conductive pattern that is associated with the step portion but also the substrate contact which corresponds to a substrate-connected electrode of an ordinary TEG is provided. The pad and the substrate contact enable electrical evaluation of a residue that has occurred in a portion, facing the step portion, of the conductive pattern.

(2) The semiconductor device according to item (1), wherein the conductive pattern is part of a capacitor structure having a metal-oxide-semiconductor (MOS) structure.

According to this semiconductor device, since the conductive pattern is part of a capacitor structure, a test can be performed in such a manner that charge stored in the capacitor is not influenced by a residue of the conductive pattern which tends to occur in the step portion. That is, the charge storage performance of the capacitor can be evaluated.

(3) The semiconductor device according to item (1) or (2), wherein the step portion is formed by an edge of a gate insulating film which is an underlying layer of the conductive pattern.

When an edge of the gate insulating film as the underlying layer of the conductive pattern is rounded, a residue is prone to occur in the step portion at the time of patterning for formation of the conductive pattern. However, this semiconductor device makes it possible to detect such a residue reliably even if it occurs. That is, the influence of the insulating film as the underlying layer of the conductive pattern where residues tend to occur can be evaluated reliably.

(4) The semiconductor device according to item (3), wherein the step pattern is a first conductor formed on a step portion and having an insulating layer on its surface, and the conductive pattern is a second conductor which is disposed adjacent to the first conductor via the insulating layer.

In this semiconductor device, since the first conductor is associated with the step portion and the second conductor is disposed adjacent to the step portion of the first conductor, second conductors tend to be short-circuited with each other because of a residue that is caused by the step portion. However, occurrence of a residue can be detected reliably. That is, short-circuiting that occurs between the second wiring layers facing both ends of the step portion due to a residue occurring in the step portion can be evaluated.

(5) The semiconductor device according to item (4), wherein the second conductor is in contact with a side end portion, in a longitudinal direction, of the first conductor.

According to this semiconductor device, since the second conductor is in contact with a side end portion, in a longitudinal direction, of the first conductor, second conductors can be short-circuited with each other via a residue occurring along the first conductor. A residue can thus be detected reliably.

(6) The semiconductor device according to anyone of items (1) to (5), wherein test signals which are input to the pad and the contact include a signal for a short-circuiting test and a signal for an oxide film time-dependent breakdown (TDDB) test.

In this semiconductor device, a signal for a short-circuiting test or a signal for a TDDB test is input to the pad and the contact. This enables not only a short-circuiting check of a residue occurring in a portion, facing the step portion, of the conductive pattern but also evaluation of a residue that does not cause short-circuiting but may cause leakage via the insulating film in the future due to electric field concentration there (i.e., time-dependent breakdown of the insulating film).

With attention paid to the fact that residues occur particularly in step portions, the step pattern which is associated with the step portion formed in the underlying layer of conductive patterns, the conductive pattern adjacent to the step pattern, the pad which is electrically connected to the conductive pattern, and a substrate contact which is electrically connected to the semiconductor substrate are provided on the semiconductor substrate. Therefore, the pad and the substrate contact enable electrical evaluation, for the conductive pattern, of a residue occurring in the step portion. This enables electrical evaluation of a residue (stringer) of the conductive pattern including one that does not cause short-circuiting, as a result of which a process variation can be detected with high accuracy.

### BRIEF DESCRIPTION OF THE DRAWINGS

FIG. 1 is a plan view of a semiconductor device according to the present invention.

FIG. 2 is a sectional view taken along line A-A in FIG. 1.

FIG. 3 is an enlarged plan view of an important part of the semiconductor device of FIG. 1.

FIG. 4 is an enlarged perspective view of a step portion shown in FIG. 3.

FIG. 5 is a plan view of a semiconductor device according to a second embodiment of the invention.

FIG. 6 is an enlarged plan view of an important part of the semiconductor device of FIG. 5.

FIG. 7 is an enlarged perspective view of a step portion shown in FIG. 6.

FIGS. 8A and 8B are sectional views showing a modification of the step portion, and FIGS. 8A and 8B show states before and after electrode patterning, respectively.

### DESCRIPTION OF SYMBOLS

11: Silicon wafer (semiconductor substrate)
13a, 33a: First-layer electrode (first conductor, conductive pattern)
13aa, 33aa: at least part of conductive layer as conductive pattern
13b, 33b: Second-layer electrode (second conductor, conductive pattern)
23, 31: Test element
100, 200: Solid-state imaging device (semiconductor device)
PAD1, PAD2, PAD3, PAD4: Pad
PAD5: Substrate contact

### DETAILED DESCRIPTION OF THE INVENTION

A preferred embodiment of the present invention will be hereinafter described with reference to the drawings.

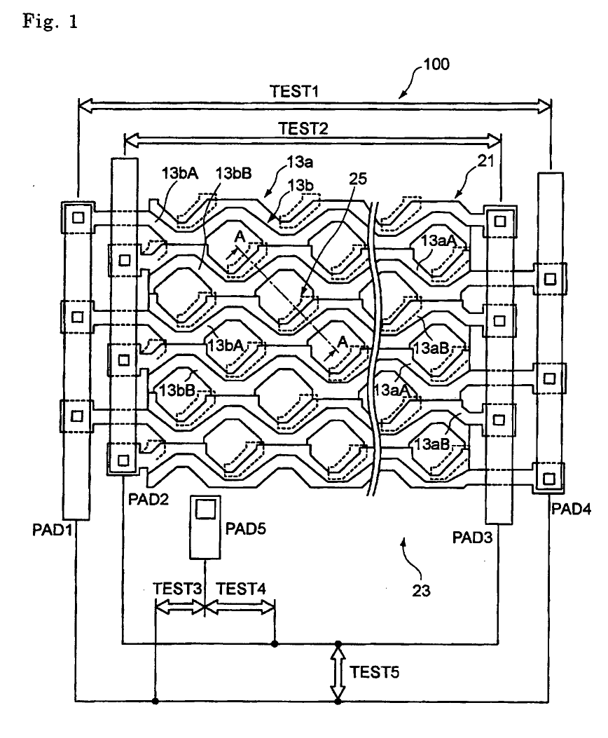

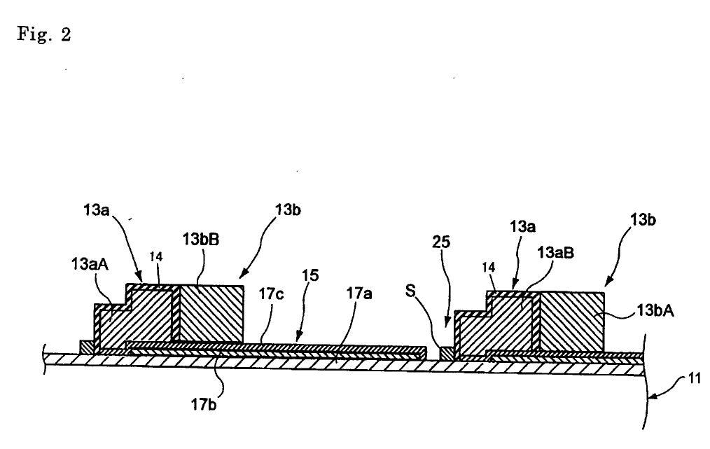

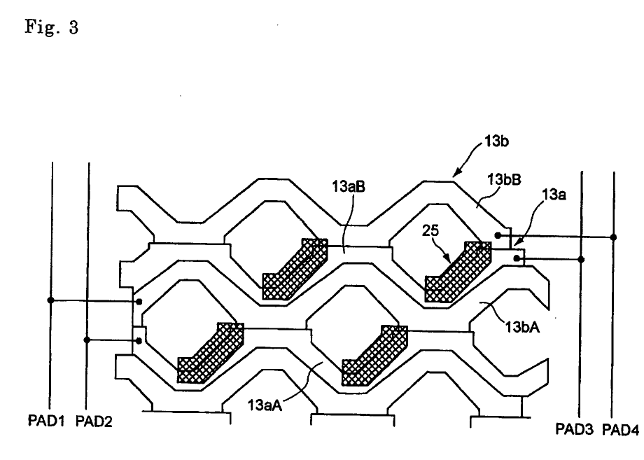

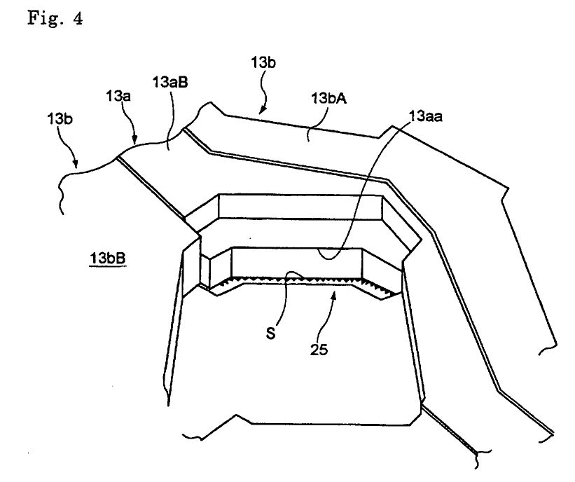

FIG. 1 is a plan view of a semiconductor device according to the invention. FIG. 2 is a sectional view taken along line A-A in FIG. 1. FIG. 3 is an enlarged plan view of an important part of the semiconductor device of FIG. 1. FIG. 4 is an enlarged perspective view of a step portion shown in FIG. 3.

A CCD solid-state imaging device 100 as an exemplary semiconductor device according to the embodiment will now be described. As shown in FIGS. 1 and 2, in the solid-state imaging device 100, charge transfer electrodes formed on a silicon wafer 11 consist of first-layer electrodes (POLY1, first conductors) 13a and second-layer electrodes (POLY2, second conductors) 13b and patterns of a silicon nitride film 17b of an ONO film 15 as a gate insulating film are formed by etching.

More specifically, the gate electrodes (13a and 13b) as the charge transfer electrodes which are made of polysilicon or amorphous silicon are formed on the gate insulating film having the ONO structure which is formed on the surface of the silicon wafer 11. The gate insulating film is a lamination film (ONO film 15) which consists of a bottom oxide film 17a which is a silicon oxide film (SiO₂), a silicon nitride film (SiN) 17b formed on the bottom oxide film 17a, and a silicon oxide film (SiO₂) 17c formed on the silicon nitride film 17b.

In the solid-state imaging device 100, plural photodiodes (not shown) are formed in p-type impurity layers which are isolated from each other by device isolation regions (not shown) and signal transfer electrodes 21 for transferring signal charges detected by the photodiodes are snaked between the photodiodes. Charge transfer channels (not shown) where signal charges are moved being transferred by the charge transfer electrodes 21 are snaked so as to extend in a direction that crosses the extending direction of the charge transfer electrodes 21.

An overflow barrier layer which is a p-type semiconductor layer is formed under the p-type impurity layers, whereby charges can be drawn out by applying a voltage to it. The first-layer electrodes 13a and the second-layer electrodes 13b are formed on the surfaces of the charge transfer regions via the gate insulating film so as to be arranged via interelectrode insulating films each of which consists of a silicon oxide film and an HTO film.

The solid-state imaging device 100 has a test element 23 for a dielectric breakdown test on the circuit formed by the conductive patterns on the semiconductor substrate 11. In the test element 23, step portions 25 (see FIG. 3) are formed in the underlying layer (ONO film 15) of the first-layer electrodes 13a and the second-layer electrodes 13b which are the conductive patterns. At least part of the conductive layers (conductive patterns), that is, the first-layer electrodes 13a, are formed as step patterns by forming a conductor film in an area including the areas of step portions 25 and removing it selectively by patterning. As shown in FIG. 4, a portion 13aa faces each step portion 25. As shown in FIG. 4, insulating films are interposed between the first-layer electrodes 13a and the second-layer electrodes 13b, whereby they are electrically insulated from each other.

The test element 23 is provided with pads PAD1-PAD4 which are made of Al or the like and are electrically connected to the first-layer electrodes 13a and the second-layer electrodes 13b and a substrate contact PAD5 which is electrically connected to the semiconductor substrate 11. As shown in FIG. 1, the plural second-layer electrodes 13b which are snaked so as to extend in the horizontal direction are such that second-layer electrodes 13bA and second-layer electrodes 13bB are arranged alternately in the vertical direction in the figure. The second-layer electrodes 13bA are connected to the pad PAD1 and the second-layer electrodes 13bB are connected to the pad PAD4. The plural first-layer electrodes 13a which are snaked so as to extend in the horizontal direction are such that first-layer electrodes 13aA and first-layer electrodes 13aB are arranged alternately in the vertical direction in the figure. The first-layer electrodes 13aA are connected to the pad PAD2 and the first-layer electrodes 13aB are connected to the pad PAD3.

Next, a process for forming the gate insulating film of the solid-state imaging device 100 will be outlined by referring to FIGS. 2-4 when necessary.

In this example, a gate insulating film and gate electrodes are formed after performing ion implantation to form n-type impurity regions for photodiode regions, p-type impurity (diffusion) regions, and n-type impurity regions for transfer channels. Alternatively, ion implantation may be performed after formation of electrodes using those electrodes as a mask.

First, a silicon oxide film 17a is formed by thermal oxidation on a surface p-type impurity layer of an n-type silicon wafer 11. A silicon nitride film 17b is then formed on the silicon oxide film 17a (bottom oxide film) by CVD.

The silicon nitride film 17b is removed selectively by isotropic etching, whereby step portions 25 of a gate insulating film are formed.

Then, a silicon oxide film 17c (top oxide film) is formed on the silicon nitride film 17b by CVD, whereby a gate insulating film having a three-layer structure is formed. Subsequently, a polysilicon or amorphous silicon film for formation of first-layer electrodes 13a is formed on the gate insulating film. The following description will made with an assumption that an amorphous silicon film is formed. First, a first-layer doped amorphous silicon film is formed by low-pressure CVD. Then, a resist pattern for formation of first-layer electrodes 13a (13aA and 13aB) is formed.

The first-layer doped amorphous silicon film is etched by using the resist pattern as a mask, whereby electrodes 13aA and 13aB of first-layer electrodes 13a are formed in an area including the areas of the step portions 25. In this step, the first-layer doped amorphous silicon film is etched selectively by using the silicon nitride film 17b of the gate insulating film as an etching stopper, whereby electrodes 13aA and 13aB of first-layer electrodes 13a, metal interconnections made of Al or the like, pads PAD1-PAD4, and a contact PAD5 are formed.

Then, an interelectrode insulating film 14 consisting of a silicon oxide film and an HTO film is formed by thermal oxidation on the entire substrate surface including the surfaces of the electrodes 13aA and 13aB of the first-layer electrodes 13a. Then, a second-layer doped amorphous silicon film is formed on the interelectrode insulating film by low-pressure CVD. After a desired mask is formed on the second-layer doped amorphous silicon film by photolithography, the second-layer doped amorphous silicon film is patterned by using the silicon nitride film 17b as an etching stopper, whereby second-layer electrodes 13b (13bA and 13bB) are formed. In this step, residues (stringers) occur particularly in the step portions 25 (the residue is exaggerated in the drawings).

The first-layer electrodes 13a and the second-layer electrodes 13b are electrically insulated from each other by the interelectrode insulating films which are formed around the first-layer electrodes 13a. After the above steps, the resist pattern is removed (peeled off) by ashing.

The step portions 25 shown in FIG. 4 are formed in the above manner, and the portions 13aa of the first-layer electrodes 13a are formed in the step portions 25. The residues (stringers) S occur along the bottom edges of the portions 13aa of the first-layer electrodes 13a.

A characteristic test on the semiconductor device 100 having the above-described test element 23 will be described below.

A wafer test apparatus for testing the electrical characteristics of a wafer on which integrated circuits of the semiconductor device 100 are formed performs a characteristic test on the test element 23 formed on the wafer by applying a voltage to the pads PAD1-PAD4 and the contact PAD5 of the test element 23 one by one in order via a probe card.

MOS capacitors TEG having the same structure as in the actual device are formed in the test element 23. Electrical measurements for short-circuiting checks can be performed on the first-layer electrodes 13a and the second-layer electrodes 13b by using the pads PAD1-PAD4 and the contact PAD5. Residues S that do not cause short-circuiting can be TDDB-evaluated through electrical measurements by using the substrate contact PAD5 which is formed on the silicon wafer 11. TDDB evaluation is done between the silicon wafer 11 and second-layer electrodes 13aB (see FIG. 4) via a residue (stringers) S that has occurred in the step portion 25 so as to be connected to the second-layer electrodes 13aB. If it is necessary to evaluate electric field concentrations between the first-layer electrodes 13a and the second-layer electrodes 13b in addition to electric field concentrations between the first-layer electrodes 13a or the second-layer electrodes 13b and the silicon wafer 11, TDDB evaluation can be done by performing electrical measurements between the first-layer electrodes 13a and the second-layer electrodes 13b.

The TDDB will be described below. Various models are available for TDDB failure mechanisms, and we will cite the following two models for qualitative mechanisms. The first model is a model that TDDB is caused by positive charge of impurity ions or the like. Impurity ions such as Na⁺ ions are moved to the negative pole side by long-term electric field application and captured by defects at the Si/SiO₂ interface (the trap state concentration is high). As a result, the barrier height becomes non-uniform and local current concentrations occur at low-barrier-height portions, resulting in dielectric breakdown. The second model is as follows. Electrons are injected into the conduction band of SiO₂ from the negative pole side by the tunneling effect and accelerated by an electric field in the SiO₂. Although the electrons lose energy through emission of phonons, part of them acquire kinetic energy that exceeds the band gap of SiO₂ and undergo collision ionization repeatedly. Having high mobility, these electrons pass through the SiO₂ in a very short time and are trapped by an SiO₂ film disposed in the vicinity of the positive pole. As a result, a local electric field is increased and breakdown occurs. On the other hand, since holes are low in mobility, part of them are extinguished through drift and recombination and the remaining holes are concentrated near the negative pole to form space charge, which accelerates injection of electrons. These electrons cause formation of holes and cause breakdown.

With the test element 23, TDDB evaluation (evaluation of time-dependent deterioration) of the gate insulating film is enabled by applying voltage stress to the pads PAD1-PAD4 and the contact PAD5 in a constant voltage mode, a pulse voltage mode, a ramp voltage mode, or the like or applying current stress to them in a constant current mode, a ramp current mode, or the like.

Specific evaluation patterns of short-circuiting checks and TDDB evaluation using the pads PAD1-PAD4 and the contact PAD5 will be described below. The pads PAD1 and PAD4 enable a short-circuiting check of the second-layer electrodes 13b (TEST1). The pads PAD2 and PAD3 enable a short-circuiting check of the first-layer electrodes 13a (TEST2). The pads PAD1 and PAD4 and the contact PAD5 enable evaluation of TDDB that is induced by residues S between the second-layer electrodes 13b and the silicon wafer 11 (TEST3). The pads PAD2 and PAD3 and the contact PAD5 enable TDDB evaluation between the first-layer electrodes 13a and the silicon wafer 11 (TEST4). The pair of pads PAD1 and PAD4 and the pair of pads PAD2 and PAD3 enable evaluation of TDDB that is induced by residues S between the first-layer electrodes 13a and the second-layer electrodes 13b (TEST5).

Conducting short-circuiting checks and TDDB evaluation together in the above manner makes it possible to detect even defects that are caused by residues S and do not result in short-circuiting. For example, inputting signals for short-circuiting tests or TDDB tests between the contact PAD5 and the pads PAD1-PAD4 enables not only a short-circuiting check of residues S that have occurred in portions 13aa, facing step portions 25, of first-layer electrodes 13a but also evaluation of residues S that do not cause short-circuiting but may cause leakage via the insulating film in the future due to electric field concentration there (i.e., time-dependent breakdown of the insulating film).

In the solid-state imaging device 100 according to the embodiment, residues S may occur when the second-layer electrodes 13b are formed. No short-circuiting involving a first-layer electrode 13a occurs because the first-layer electrodes 13a are covered with the interelectrode insulating films. Therefore, in the solid-state imaging device 100, residues S of the second-layer electrodes 13b do not influence the first-layer electrodes 13a.

Although basically the TEG area of the test element 23 is provided in a non-products-producing wafer by forming the same patterns as in products, the invention is not limited to such a case. A TEG area may be provided as a portion of a products-producing wafer and subjected to tests.

In the solid-state imaging device 100, with attention paid to the fact that residues S occur particularly in the step portions 25, in the structure that the step portions 25 are formed in the underlying layer of the conductive patterns in the active regions involving the conductive patterns on the semiconductor substrate 11, at least the portions 13aa are electrically connected to the conductive patterns formed in the step portions 25 and the pads PAD1-PAD4 to which test signals for a test of dielectric breakdown involving those conductive patterns and the contact PAD5 which is electrically connected to the silicon wafer 11 are formed. As a result, the pads PAD1-PAD4 and the contact PAD5 enable electrical evaluation of residues that have occurred in the portions, facing the step portions 25, of the conductive patterns. This enables electrical evaluation of residues S of the conductive patterns including ones that do not cause short-circuiting, as a result of which a process variation can be detected.

The first-layer electrodes 13a and the second-layer electrodes 13b are conductive patterns each of which is part of the metal-oxide-semiconductor (MOS) structure. Since the conductive patterns are each part of the capacitor structure, tests can be performed in such a manner that the charge stored in the capacitor is not influenced by a residue S that tends to occur in the step portion 25. That is, the charge storage performance of the capacitor can be evaluated.

In the test element 23, the step portions 25 are formed by the edges of the insulating layer as the underlying layer of the conductive patterns. When the edges of the insulating layer as the underlying layer of the conductive patterns are rounded, residues S are prone to occur in the step portions 25 at the time of patterning for formation of the conductors. Even if residues S occur, they can be detected reliably. That is, the influence of the residue-prone insulating layer as the underlying layer of the conductive patterns can be evaluated reliably.

Next, a semiconductor device according to a second embodiment of the invention will be described.

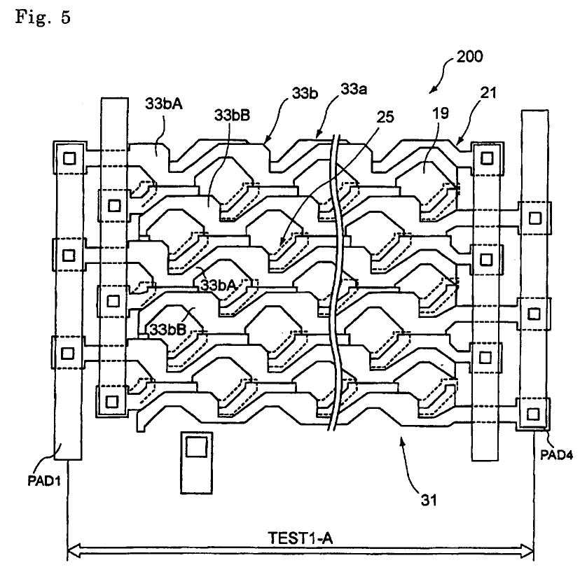

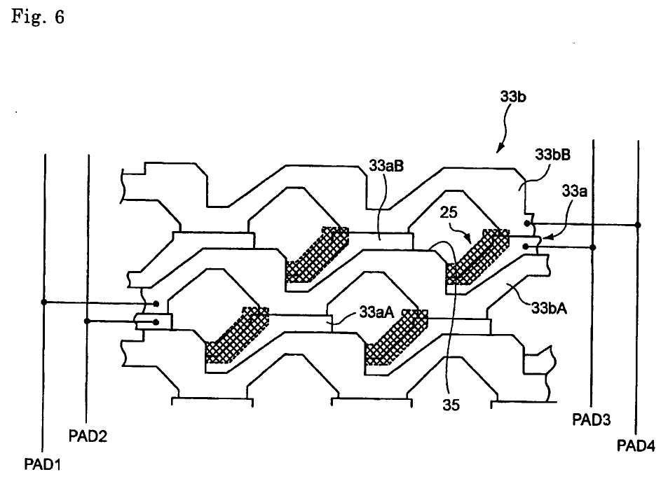

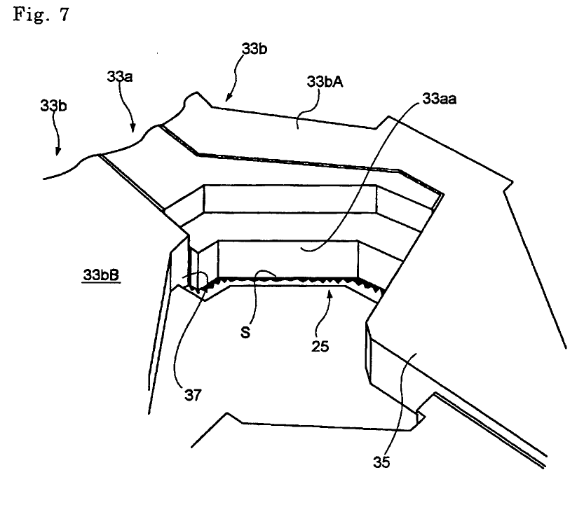

FIG. 5 is a plan view of a semiconductor device according to the second embodiment of the invention. FIG. 6 is an enlarged plan view of an important part of the semiconductor device of FIG. 5. FIG. 7 is an enlarged perspective view of a step portion shown in FIG. 6. Members and portions having equivalent ones in FIGS. 1-4 are given the same reference symbols as the latter and redundant descriptions therefor will be avoided.

The semiconductor device 200 according to this embodiment is provided with a test element 31. In the test element 31, conductive patterns consist of first-layer electrodes 33a (first conductors) that are associated with step portions 25 and second-layer electrodes 33b (second conductors) which are insulated from the first-layer electrodes 33a. The second-layer electrodes 33b are adjacent to the step portions 25 of the first-layer electrodes 33a. As shown in FIG. 7, insulating films are interposed between the first-layer electrodes 33a and the second-layer electrodes 33b, whereby they are electrically insulated from each other.

The test element 31 is provided with pads PAD1 and PAD4 which are electrically connected to the second-layer electrodes 33b. As shown in FIGS. 5 and 6, the plural second-layer electrodes 33b which are snaked so as to extend in the horizontal direction are such that second-layer electrodes 33bA and second-layer electrodes 33bB are arranged alternately in the vertical direction of the drawings. The second-layer electrodes 33bA are connected to the pad PAD1 and the second-layer electrodes 33bB are connected to the pad PAD4. At least part of the conductive layers (conductive patterns), that is, the first-layer electrodes 33a are formed by forming a conductor film in an area including the areas of step portions 25 and patterning it selectively. As shown in FIG. 7, a portion 33aa of each first-layer electrode 33a is formed so as to face a step portion 25.

Shoulders 35 are formed in the second-layer electrodes 33b so as to be adjacent to the step portions 25. That is, the second-layer electrodes 33b have the shoulders 35 which are in contact with side end portions, in the longitudinal direction, of the first-layer electrodes 33a. That is, as shown in FIG. 7, side walls 37 of the second-layer electrodes 33bB and the shoulders 35 of the second-layer electrodes 33bA are located at both ends, in the longitudinal direction, of the step portions 25. Therefore, if a residue occurs continuously in a step portion 25, the second-layer electrodes 33bB and 33bA, more specifically, the side wall 37 and the shoulder 35 which face the step portion 25, are short-circuited with each other via the residue S.

As shown in FIG. 5, in the test element 31, a check of short-circuiting, due to residues S, of the second-layer electrodes 33b (in the examples of FIG. 7, the second-layer electrodes 33bB and 33bA) can be performed by using the pads PAD1 and PAD4 (TEST1-A).

In this embodiment, the first-layer electrodes 33a are associated with the step portions 25 and the shoulders 35 of the second-layer electrodes 33b are formed adjacent to the step portions 25 of the first-layer electrodes 33a so as to be in contact with the step portions 25. Although a residue S occurring in a step portion 25 tends to cause short-circuiting between the second-layer electrodes 33b, the occurrence of the residue S can be detected reliably. That is, short-circuiting that occurs between second-layer electrodes 33b facing both ends of a step portion 25 due to a residue S occurring in the step portion 25 can be evaluated.

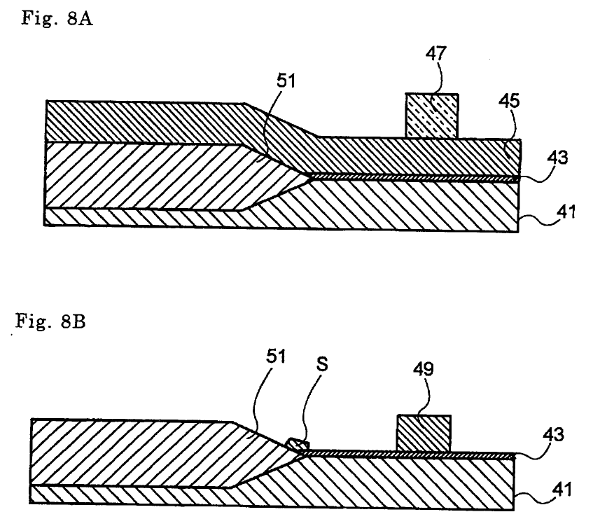

FIG. 8 is sectional views showing a modification of the step portion. Although the above-described embodiments are directed to the semiconductor devices in which residues S may occur in the step-shaped step portions 25, residues S may also occur in step portions having other, similar shapes. For example, a residue may likewise occur in a portion having a general LOCOS structure as shown in FIG. 8.

FIG. 8 shows how an electrode with a LOCOS structure is formed. FIG. 8A shows a state that a LOCOS oxide film 51 is formed on a silicon wafer 41, an SiO₂ film is formed in area other than the area of the LOCOS oxide film 51, a conductive layer 45 made of polysilicon or the like is formed in the entire area shown in the figure, and a resist 47 is formed at an electrode forming position by patterning.

When the conductive layer 45 is removed selectively by etching using the resist 47 as a mask as shown in FIG. 8B, a residue S may remain and stringers similar to the above-described ones may occur because of the step of the underlying layer at the end of the LOCOS oxide film 51.

The semiconductor device according to the invention is not limited to CCD imaging devices and the invention can also be applied to MOS imaging devices suitably.

This application is based on Japanese Patent application JP 2006-143177, filed May 23, 2006, the entire content of which is hereby incorporated by reference, the same as if fully set forth herein.

Although the invention has been described above in relation to preferred embodiments and modifications thereof, it will be understood by those skilled in the art that other variations and modifications can be effected in these preferred embodiments without departing from the scope and spirit of the invention.

What is claimed is:

1. A semiconductor device comprising a test element for a dielectric breakdown test on conductive patterns formed on a semiconductor substrate, wherein the test element comprises:
a step pattern which is associated with a step portion formed in an underlying layer which is formed on the semiconductor substrate;
a conductive pattern adjacent to the step pattern, the conductive pattern being formed by forming a conductive layer on the step pattern and removing at least part of the formed conductive layer selectively by patterning;
a pad which is electrically connected to the conductive pattern; and
a substrate contact which is electrically connected to the semiconductor substrate.

2. The semiconductor device according to claim 1, wherein the conductive pattern is part of a capacitor structure having a metal-oxide-semiconductor structure.

3. The semiconductor device according to claim 1, wherein the step portion is formed by an edge of a gate insulating film which is an underlying layer of the conductive pattern.

4. The semiconductor device according to claim 2, wherein the step portion is formed by an edge of a gate insulating film which is an underlying layer of the conductive pattern.

5. The semiconductor device according to claim 3, wherein the step pattern is a first conductor formed on the step portion, and the conductive pattern is a second conductor which is electrically insulated from the first conductor.

6. The semiconductor device according to claim 4, wherein the step pattern is a first conductor formed on the step portion, and the conductive pattern is a second conductor which is electrically insulated from the first conductor.

7. The semiconductor device according to claim 5, wherein the second conductor is in contact with a side end portion, in a longitudinal direction, of the first conductor.

8. The semiconductor device according to claim 6, wherein the second conductor is in contact with a side end portion, in a longitudinal direction, of the first conductor.

9. The semiconductor device according to claim 1, wherein test signals which are input to the pad and the contact include a signal for a short-circuiting test and a signal for an oxide film time-dependent breakdown test.

10. The semiconductor device according to claim 2, wherein test signals which are input to the pad and the contact include a signal for a short-circuiting test and a signal for an oxide film time-dependent breakdown test.

11. The semiconductor device according to claim 3, wherein test signals which are input to the pad and the contact include a signal for a short-circuiting test and a signal for an oxide film time-dependent breakdown test.

12. The semiconductor device according to claim 4, wherein test signals which are input to the pad and the contact include a signal for a short-circuiting test and a signal for an oxide film time-dependent breakdown test.

13. The semiconductor device according to claim 5, wherein test signals which are input to the pad and the contact include a signal for a short-circuiting test and a signal for an oxide film time-dependent breakdown test.

14. The semiconductor device according to claim 6, wherein test signals which are input to the pad and the contact include a signal for a short-circuiting test and a signal for an oxide film time-dependent breakdown test.
